(19) United States
(12) Patent Application Publication
(10) Pub. No.: US 2016/0005799 A1
(43) Pub. Date: Jan. 7, 2016

(54) THIN FILM TRANSISTOR, TFT ARRAY SUBSTRATE, MANUFACTURING METHOD THEREOF AND DISPLAY DEVICE

(71) Applicant: BOE TECHNOLOGY GROUP CO., LTD, Beijing (CN)

(72) Inventors: Dongfang WANG, Beijing (CN); Wei LIU, Beijing (CN); Haijing CHEN, Beijing (CN)

(73) Assignee: BOE TECHNOLOGY GROUP CO., LTD., Beijing (CN)

(21) Appl. No.: 14/429,867

(22) PCT Filed: Apr. 30, 2014
(86) PCT No.: PCT/CN2014/076625

§ 371 Date: Mar. 20, 2015

(30) Foreign Application Priority Data
Dec. 30, 2013 (CN) 201310746662.9

(51) Int. Cl. H01L 27/32; H01L 29/66; H01L 29/786

(52) U.S. Cl. CPC H01L 27/3244; H01L 29/786; H01L 29/66742

(57) ABSTRACT

A TFT, a TFT array substrate, a manufacturing method thereof and a display device are disclosed. A source of the TFT includes a first source portion (51). A drain of the TFT includes a first drain portion (52). The first source portion (51) and the first drain portion (52) are disposed in the same layer as an active layer and respectively at opposite sides of the active layer (5). The first source portion (51) and the first drain portion (52) are in direct contact to the active layer (5) respectively. The capacitance will not be generated between the first source/drain portion (51, 52) and the gate (2), because the first source/drain portion (51,52) and the gate (2) are disposed without overlapping with each other or with a small-area overlapping region. The breakdown of a gate insulation layer caused by too large voltage of the source/drain or too many charges accumulated on the source/drain can be also avoided.

### TECHNICAL FIELD

Embodiments of the present invention relates to a field of manufacturing displays, particularly relates to a thin film transistor (TFT), a TFT array substrate comprising the TFT, a manufacturing method thereof, and a display device comprising the TFT array substrate.

### BACKGROUND

Organic Light Emitting Diode (OLED) displays have attracted considerable attention duo to the advantages such as self-illumination, wide viewing angel, high contrast, thin and compact, and significant power saving. OLED displays are becoming the mainstream of the next generation display technology and will be widely used. Typically, an OLED display has a stack structure which includes a cathode, an anode, and an organic light emitting layer formed between the cathode and the anode. The organic light emitting layer is made of organic light emitting compounds, such as small molecule material, polymer material, or other organic light emitting material. According to the different drive schemes, OLED displays can be classified into Active Matrix and Passive Matrix types.

In Active Matrix Organic Light Emitting Diode (AMOLED) display, a drive TFT of the array substrate is used to drive the organic light emitting layer by supplying the current for it, such that the organic light emitting layer emits light. FIG. 1 schematically illustrates a cross section view of a known bottom-gate TFT array substrate of AMOLED, which comprises:

a gate a2 and a store capacitance lower electrode a3 disposed on a base substrate a1;

a gate insulation layer a4 disposed on both the gate a2 and the store capacitance lower electrode a3;

an active layer a5 disposed on the gate insulation layer a4 and corresponding the position of the gate a2;

an etch stop layer (ESL) a6 disposed on the active layer 5a, wherein two ESL holes penetrating through the etch stop layer a6 and a via hole penetrating through both the etch stop layer a6 and the gate insulation layer a4 are formed in the etch stop layer a6; the store capacitance lower electrode a3 is connected to a gate line of a drive TFT in a pixel unit through the via hole for switching on the drive TFT;

a source/drain a7 disposed on the etch stop layer a6, wherein the source/drain a7 are respectively connected to the active layer a5 through the ESL hole; and

a passivation layer a8 disposed on the source/drain a7, and an upper electrode a9 of the store capacitance.

The problem of the known bottom-gate TFT array substrate is that: If the voltage of the source/drain is too large, or if the charges accumulated on the source/drain are too many, the breakdown of the gate insulation layer will tend to occur due to a capacitance may be generated in overlapping region between the source/drain and the gate. As a result, the TFT array substrate has to be scrapped.

### SUMMARY

Embodiments of the present invention provide a thin film transistor (TFT), TFT array substrate, a manufacturing method thereof and a display device.

In first aspect, an embodiment of the present invention provides a thin film transistor (TFT), a source of which comprises a first source portion and a drain of which comprises a first drain portion, wherein the first source portion and the first drain portion are disposed in the same layer as an active layer of the TFT and at two opposite sides of the active layer respectively, and each of the first source portion and the first drain portion is in direct contact with the active layer.

In second aspect, an embodiment of the present invention provides TFT array substrate, comprising a plurality of pixel units, wherein each of the pixel units comprises a switch TFT, and the switch TFT is any one of the TFTs according to above embodiments.

In third aspect, an embodiment of the present invention provides a display device comprising any one of the TFT array substrates according to above embodiments.

In fourth aspect, an embodiment of the present invention provides a method of manufacturing a TFT, comprising:

forming a first source portion pattern of a source, a first drain portion pattern of a drain, and an active layer pattern on a base substrate by patterning process, wherein the first source portion and the first drain portion are respectively disposed at two opposite sides of an active layer and in direct contact with the active layer; and

performing a conductivity treatment on the first source portion and the first drain portion.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 schematically illustrates a cross section view of a known bottom-gate TFT array substrate of AMOLED;

FIG. 2 schematically illustrates the principle of a gray tone mask used in an embodiment of the present invention;

FIG. 3 schematically illustrates a cross section view of a TFT array substrate according to an embodiment of the present invention;

FIG. 4 is a flow chart illustrating a method for manufacturing a TFT array substrate according to an embodiment of the present invention;

FIGS. 5A-5H illustrate cross section views of the TFT array substrate in the manufacturing method according to an embodiment of the present invention;

FIG. 6 schematically illustrates a top view of one of pixel units on the TFT array substrate which is manufactured by the method according to an embodiment of the present invention.

### DETAILED DESCRIPTION

In order to make objects, technical details and advantages of the embodiments of the invention apparent, hereinafter, the technical solutions of the embodiments of the invention will be described in a clearly and fully understandable way in connection with the drawings related to the embodiments of the invention. It is obvious that the described embodiments are just a part but not all of the embodiments of the invention. Based on the described embodiments of the invention, those ordinarily skilled in the art can obtain other embodiment(s), without any inventive work, which should be within the scope sought for protection by the invention.

Unless otherwise defined, all the terms (including technical and scientific terms) used herein have the same meaning as commonly understood by one of ordinary skill in the art to which this invention belongs. The terms “first”, “second” and the like used in the specification and claims are intended to differentiate different components, rather than to show the order, number or importance. Also, the terms “one”, “one of” and the like are intended to show the presence of at least one element, but cannot be construed as limitation on the number. The terms “connecting”, “connected” and the like shall not be limited to physical or mechanical connection, and may also include electrically connection, not matter directly or indirectly. The terms “upper”, “lower”, “left” and “right” are used herein merely to show the relative position, and when an absolute position of an object to be described is changed, the relative position thereof will be changed correspondingly.

Embodiments of the present invention provide a thin film transistor (TFT), a TFT array substrate, a manufacturing method thereof and a display device. With such configurations, the breakdown of the gate insulation layer usually occurred in the known bottom-gate TFT array substrate can be avoid.

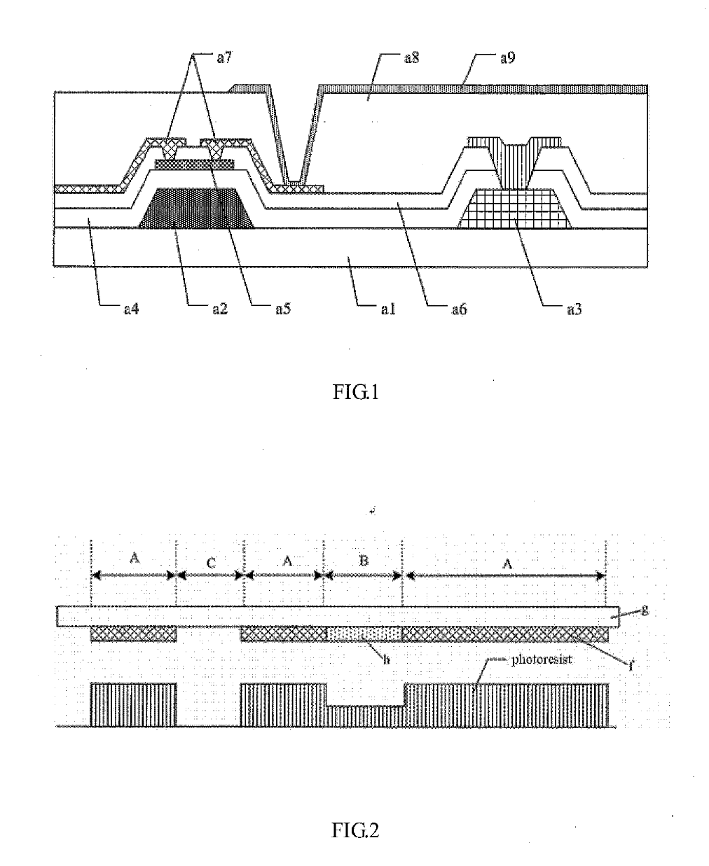

Firstly, the principle of a gray tone mask used in embodiments of the present invention will be explained. As illustrated in FIG. 2, the gray tone mask typically comprises a transparent quartz glass substrate g, an opaque film f and a semi-transparent film h formed on the quartz glass substrate g. The opaque film f is made of light blocking material, and the semi-transparent film h allows a part of light to be transmitted through. The gray tone mask comprises a completely-light-blocking region A, a partially-light-transmitting region B and a completely-light-transmitting region C.

Taking a positive photoresist as an example. A layer of photoresist (PR) is firstly coated on a film material which needs to be patterned; and then, the light emitted from a light source irradiates the gray tone mask. Because the light cannot transmit through the completely-light-blocking region A, the region A is formed as a non-exposure region; thus, a portion of the photoresist beneath the non-exposure region is completely retained after development, thereby forming a photoresist-completely-retained region. Because a part of the light can transmit through the partially-light-transmitting region B, the region B is formed as a partial exposure region; thus, a portion of the photoresist beneath the partial exposure region is partially removed after development, thereby forming a photoresist-partially-retained region. Because the light totally transmits through the completely light-transmitting region C, the region C is formed as a full exposure region; thus, a portion of the photoresist beneath the full exposure region is completely removed after development, thereby forming a photoresist-completely-removed region.

Embodiments of the present invention will be described below in conjunction with the accompanying drawings, and it should be understood that the embodiments described herein are only used for describing and illustrating the present invention instead of limiting the present invention

An embodiment of the present invention provides a thin film transistor (TFT), a source of which comprises a first source portion, and a drain of which comprises a first drain portion, where the first source portion and the first drain portion are disposed in the same layer as an active layer of the TFT and disposed at two opposite sides of the active layer respectively, and each of the first source portion and the first drain portion is in direct contact with the active layer.

In the TFT according to the embodiment of the present invention, the capacitance cannot be generated between the first source/drain portion and the gate, because the first source/drain portion and the gate are disposed without overlapping with each other or with a small-area overlapping region. The breakdown of a gate insulation layer caused by too large voltage of the source/drain or too many charges accumulated on the source/drain can be avoided.

In the TFT according to the embodiment of the present invention, the material for the first source portion and the first drain portion is obtained by subjecting the same material as the active layer to a conductivity treatment.

For example, the active layer is made of semiconductor material. The first source portion and the first drain portion are made of the semiconductor material which has been subjected to the conductivity treatment. As the first source portion and the first drain portion are made of the treated material and becomes conductors, the normal switch work of the TFT is guaranteed. The semiconductor material can be indium gallium zinc oxide (IGZO), zinc indium tin oxide (ITZO), hafnium indium zinc oxide (HIZO), zinc oxide (ZnO), tin oxide (SnO), tin dioxide (SnO₂), copper oxide (Cu₂O) or ZnON.

In an embodiment, the TFT further comprises an etch stop layer formed on the active layer, the first source portion as well as the first drain portion. The source further comprises a second source portion formed on the etch stop layer, and the drain further comprises a second drain portion formed on the etch stop layer, where the second source portion is electrically connected to the first source portion, and the second drain portion is electrically connected to the first drain portion. For example, two first via holes through the etch stop layer are formed in the etch stop layer and respectively above the first source portion and the first drain portion. The second source portion is connected to the first source portion through one first via hole above the first source portion, and the second drain portion is connected to the first drain portion through the other via hole above the first drain portion.

The TFT according to the embodiment of the present invention may be a bottom-gate TFT (the gate of the TFT is formed under the active layer) or a top-gate TFT (the gate of the TFT is formed on the active layer). In addition, the TFT according to the embodiment of the present invention may be a dual-gate TFT or a multi-gate TFT, the structures of which are similar with the bottom-gate TFT or the top-gate TFT and will not be iterated here.

Another embodiment of the present invention provides a TFT array substrate, which comprises a plurality of pixel units, each pixel unit comprises a switch TFT, which is the TFT of any one of the above embodiments of the present invention.

In each pixel unit of the TFT array substrate according to the embodiment of the present invention, a first source portion of a source and a first drain portion of a drain are formed in the same layer as the active layer and disposed at two opposites side of the active layer respectively, and each of the first source portion and the first drain portion is in direct contact with the active layer. The capacitance cannot be generated between the first source/drain portion and the gate, because the first source/drain portion and the gate are disposed without overlapping with each other or with a small-area overlapping region. The breakdown of a gate insulation layer caused by too large voltage of the source/drain or too many electrostatic charges accumulated on the source/drain can be avoided, thereby increasing the defect-free ratio of the TFT array substrate.

In case the TFT array substrate is an active matrix organic light emitting display (AMOLED) array substrate, each pixel unit further comprises a drive TFT besides the switch TFT. The drive TFT is the TFT of any one of above embodiments of the present invention.

In an example, the AMOLED array substrate further comprises a gate, a gate insulation layer, an etch stop layer, and a store capacitance lower electrode. A second via hole penetrating through both the etch stop layer and the gate insulation layer is formed in the etch stop layer. The store capacitance lower electrode is connected to the gate of the drive TFT through the second via hole, and the store capacitance lower electrode is disposed in the same layer as the gate of the switch TFT.

In an example, a connection metal layer in the same layer as the second source portion and the second drain portion of the switch TFT is formed in the second via hole. The gate of the drive TFT is connected to the store capacitance lower electrode through the connection metal layer.

In an example, the AMOLED array substrate further comprises a store capacitance upper electrode, which is electrically connected to the second drain portion of the switch TFT.

In an example, the AMOLED array substrate further comprises a pixel electrode, one of the source and drain of the drive TFT is connected to the power line, and the other is connected to the pixel electrode.

In the embodiment, the gate of the drive TFT in each pixel unit is connected to the source or the drain of the switch TFT in the same pixel unit through the store capacitance upper electrode. In other embodiments, the gate of the drive TFT in each pixel unit is directly connected to the source or the drain of the switch TFT in the same pixel unit as the drive TFT. No matter which connection manner is used, the purpose is to make the store capacitance generated between the data voltage and the power voltage and keep their voltages.

The switch TFT (and/or drive TFT) of TFT array substrate according to the embodiment may be a bottom-gate or top-gate TFT, and also may be a dual-gate or multi-gate TFT.

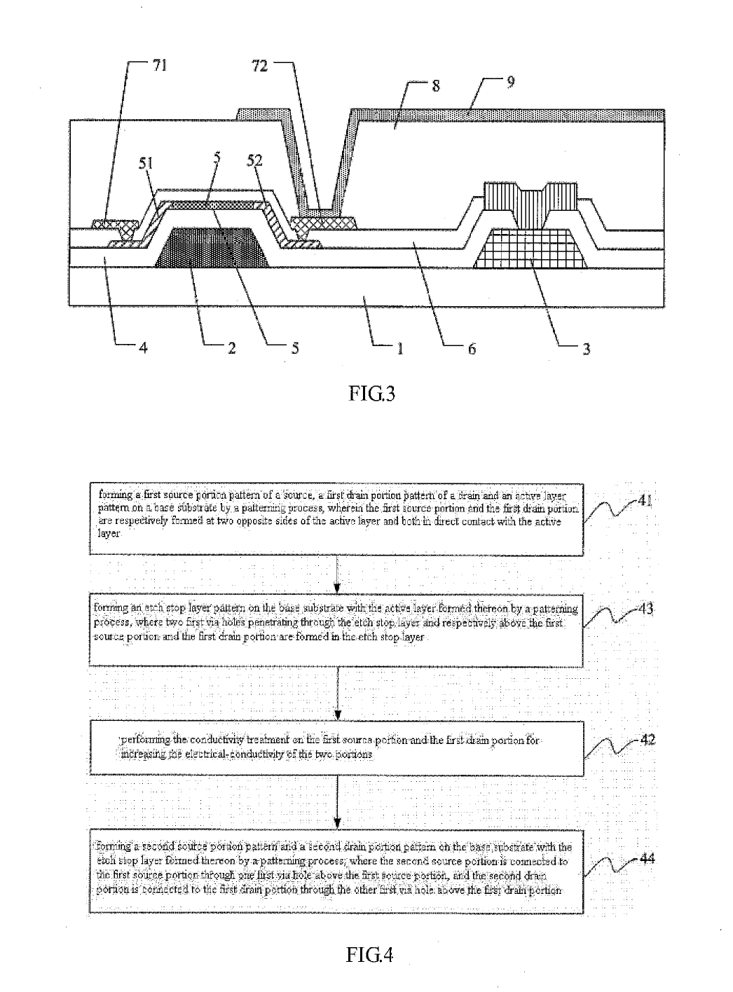

For example, FIG. 3 schematically illustrates a cross section of a pixel unit of a typical bottom-gate TFT array substrate. Other pixel units are same as it and will not be iterated here. As illustrated in FIG. 3, the TFT array substrate comprises:

a substrate 1;

a gate 2 and a store capacitance lower electrode 3 disposed on the base substrate 1;

a gate insulation layer 4 disposed on the gate 2 and the store capacitance lower electrode 3;

an active layer 5, a first source portion 51, a first drain portion 52 disposed on the gate insulation layer 4, the active layer 5 corresponding to the position of the gate 2, the first source portion 51 and the first drain portion 52 being disposed at two opposite sides (as illustrated in drawing) of the active layer respectively and both in direct contact with the active layer 5, where the first source portion 51, the first drain portion 52 and the active layer 5 is an integral structure, the active layer 5 is made of semiconductor material, the material for the first source portion and the first drain portion is obtained by subjecting the same material as the active layer to a conductivity treatment;

an etch stop layer 6 disposed on the active layer 5, where two first via holes and a second via hole are formed in the etch stop layer 6, the two first via holes penetrating through the etch stop layer 6, the second via hole penetrating through both the etch stop layer 6 and a gate insulation layer 4 and being disposed above the store capacitance lower electrode 3; where the store capacitance lower electrode 3 is connected to the gate of the drive TFT in same pixel unit through the second via hole (the structure of the drive TFT is not illustrated in drawings, which is similar with the structure of the switch TFT);

a second source portion 71 and a second drain portion 72 disposed on the etch stop layer 6, where the second source portion 71 is connected to the first source portion 51 through one of the first via holes, and the second drain portion 72 is connected to the first drain portion 52 through the other first via hole;

a passivation layer 8 disposed on the second source portion 71 and the second drain portion 72, where a third via hole is formed in the passivation layer 8, the third via hole penetrating through the passivation layer 8 and disposed over the second drain portion 72; and

a store capacitance upper electrode 9 disposed on the passivation layer 8, where the store capacitance upper electrode 9 is connected to the second drain portion 72 through the third via hole.

Another embodiment of the present invention further provides a display device, which comprises the TFT array substrate of any one of above embodiments of the present invention.

The display device according to the embodiment can be used in a Liquid Crystal Display (LCD), an electronic paper, an Organic Light Emitting Diode (OLED) panel, a mobile phone, a tablet PC, a television set, a display screen, a laptop computer, digital photoframe, a navigator, or any other products and components having display function.

According to different drive schemes, the OLED display panel can be classified into active matrix and passive matrix types.

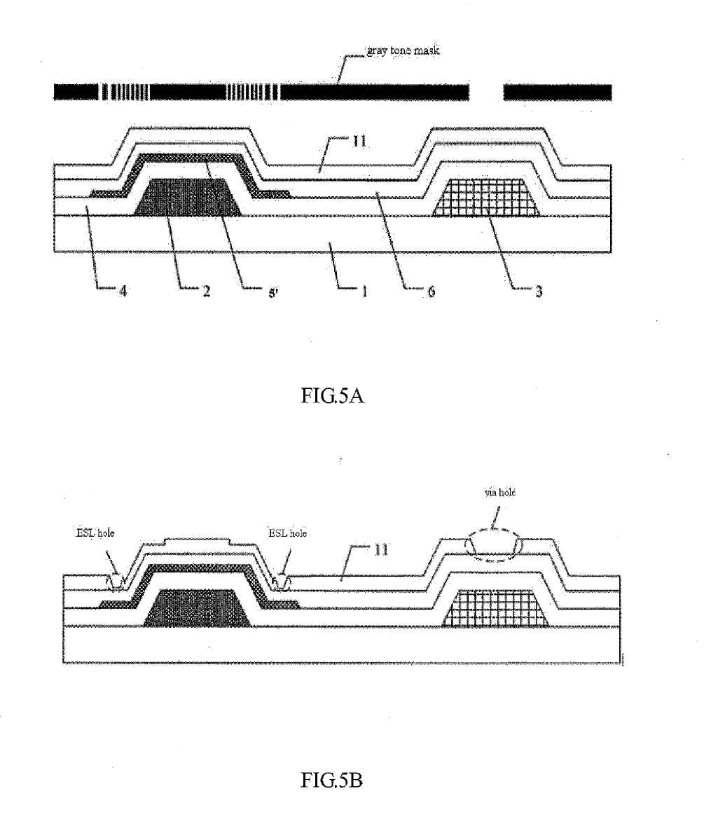

As illustrated in FIG. 4, still another embodiment of the present invention further provides a method for manufacturing a TFT array substrate, the method comprises:

Step 41, forming a first source portion pattern of a source, a first drain portion pattern of a drain and an active layer pattern on a base substrate by a patterning process, wherein the first source portion and the first drain portion are respectively formed at two opposite sides of the active layer and both in direct contact with the active layer.

In this step, the active layer is made of semiconductor material, such as indium gallium zinc oxide (IGZO), zinc indium tin oxide (ITZO), hafnium indium zinc oxide (HIZO), zinc oxide (ZnO), tin oxide (SnO), tin dioxide (SnO₂), copper oxide (Cu₂O) or ZnON; the material of the first source portion and the first drain portion is obtained by subjecting the same material as the active layer to a conductivity treatment, in order to increase the electrical-conductivity of the first source portion and the first drain portion.

Step 42, performing the conductivity treatment on the first source portion and the first drain portion for increasing the electrical-conductivity of the two portions.

In an example, the conductivity treatment in step 42 comprises hydrogen plasma treatment.

For example, the conductivity treatment can be a plasma treatment using NH3 gas.

The orders of manufacturing some known structures or components of the TFT array substrate, such as the gate, the gate insulation layer, the passivation layer, the store capacitance upper electrode, and the pixel electrode are not limited in the embodiment. The TFT array substrate in the embodiment may be a top-gate TFT array substrate, a bottom-gate TFT array substrate, a dual-gate TFT array substrate, or a multi-gate TFT array substrate.

In each pixel unit of the TFT array substrate formed by the manufacturing method according to the embodiment, the capacitance cannot be generated between the first source/drain portion and the gate, because the first source/drain portion and the gate are disposed without overlapping with each other or with a small-area overlapping region. The breakdown of a gate insulation layer caused by too large voltage of the source/drain or too many charges accumulated on the source/drain can be avoided, thereby increasing the defect-free ratio of the TFT array substrate.

In an example, after step 41 and before step 42, the method further comprises:

Step 43, forming an etch stop layer pattern on the base substrate with the active layer formed thereon by a patterning process, where two first via holes penetrating through the etch stop layer and respectively above the first source portion and the first drain portion are formed in the etch stop layer.

In this step, the etch stop layer may be made of at least one of SiNx and SiOx; the second source portion and the second drain portion may be made of one metal selected from molybdenum (Mo), aluminum (Al), copper (Cu), tungsten (W) or an alloy of at least two metals among them.

In an example, after step 42, the method further comprises:

Step 44, forming a second source portion pattern and a second drain portion pattern on the base substrate with the etch stop layer formed thereon by a patterning process; where the second source portion is connected to the first source portion through one first via hole above the first source portion, and the second drain portion is connected to the first drain portion through the other first via hole above the first drain portion.

In this step, the second source portion and the second drain portion can be made of one metal selected from molybdenum (Mo), aluminum (Al), copper (Cu), tungsten (W) or an alloy of at least two metals among them.

As an implementation, in case the array substrate is a top-gate TFT array substrate, the method further comprises the following step after step 44:

forming a gate and a passivation layer on the base substrate which with the second source portion and the second drain portion formed thereon by a patterning process.

In this step, the etch stop layer may be made of at least one of SiNx and SiOx; the gate may be made of one metal selected from molybdenum (Mo), aluminum (Al), copper (Cu), tungsten (W) or an alloy of at least two metals among them.

As another implementation, in case the array substrate is a bottom-gate TFT array substrate, the method further comprises the following step before step 41:

forming a gate pattern and a gate insulation layer on the base substrate by a patterning process.

In this step, the gate may be made of one metal selected from molybdenum (Mo), aluminum (Al), copper (Cu), tungsten (W) or an alloy of at least two metals among them; the gate insulation layer may be made of at least one of SiNx and SiOx.

In this implementation, if the TFT array substrate is an AMOLED array substrate, the method comprises the following step at the same time as forming a gate pattern on the base substrate:

forming a store capacitance lower electrode pattern in the same layer as the gate pattern.

In an example, the step 43 of forming an etch stop layer pattern on the base substrate with the active layer formed thereon by a patterning process further comprises:

forming a second via hole in the etch stop layer, the second via hole penetrating through both the etch stop layer and the gate insulation layer; where the store capacitance lower electrode is connected to the gate of the drive TFT through the second via hole.

The patterning process used in embodiments of the present invention at least comprises: coating a photoresist, exposing, developing, etching and stripping the photoresist. Taking a positive photoresist as an example.

For example, the step 43 of forming an etch stop layer pattern on the base substrate with the active layer formed thereon by a patterning process comprises:

A1, coating an insulation film on the base substrate with the active layer formed thereon, and coating the photoresist on the insulation film.

A2, exposing and developing the photoresist with a gray tone mask, to form a photoresist-completely-retained region, a photoresist-completely-removed region and a photoresist-partially-retained region; where the photoresist-partially-retained region corresponds to the region where the first source portion of the source and the first drain portion of the drain to be formed; the photoresist-completely-removed region corresponds to the region where the second via hole is to be formed; the photoresist-completely-retained region corresponds to the region on the base substrate other than above two regions;

the photoresist-partially-retained region has a stepped shape, namely, in the photoresist-partially-retained region, the thickness of the photoresist formed in the region corresponding to the region where the first via holes are to be formed is less than the thickness of the photoresist in other regions of the photoresist-partially-retained region.

A3, forming the second via hole which penetrates through both the etch stop layer and the gate insulation layer by a single etching process, and removing the photoresist in the photoresist-partially-retained region corresponding to the position of the first via holes by Reactive Ion Etching (RIE) process.

In this step, the photoresist covers other regions of the TFT array substrate expect the region where the second via hole is located. Thus, only the insulation film formed in the region where the second via hole is located is etched, the insulation film formed in other regions can not be etched because of the protection of the photoresist, which avoids the short circuit between the drain/source and the gate caused by over-etching the gate insulation layer. After forming the second via hole, the residual photoresist in the second via hole is simultaneously removed during the RIB process of removing the photoresist in the photoresist-partially-retained region.

Alternatively, while the via hole having a depth that less than the depth of the second via hole is formed (i.e. the store capacitance lower electrode has not been exposed), the photoresist in the photoresist-partially-removed region is removed. In the subsequent etching step, the other part of the second via hole is formed in the same step as the first via holes for saving the etching time.

In this step, only the organic film (such as photoresist) is removed by RIE process, thus, the other structure of the array substrate will not be damaged.

A4, forming first via holes by a single etching process, the first via holes penetrating through the etch stop layer; alternatively, forming the first via holes and the second via hole at the same time by a single etching process, the first via holes penetrating through the etch stop layer and the second via hole penetrating through both the etch stop layer and the gate insulation layer;

In this step, because the photoresist covers other regions (i.e. photoresist-completely-retained region) of the etch stop layer except the region where the first via holes are to be formed, only the region where the first via holes are located is etched while other structure is not damaged, so that the first via holes could be formed, which further avoid the problem of over-etching the gate insulation layer.

A5, removing the photoresist in the photoresist-partially-retained region by RIE process to expose the first source portion and the first drain portion under the photoresist-partially-retained region.

In this step, during the RIE process, the residual photoresist in the first via holes is also removed.

Because the thickness of the photoresist in the photoresist-completely-retained region is larger than the thickness of the photoresist in the photoresist-partially-retained region, the photoresist in the photoresist-completely-retained region is retained with a certain thickness.

In this step, only the organic film (such as photoresist) is removed by RIE process, thus, the other structure of the array substrate will not be damaged.

A6, performing a conductivity treatment (such as hydrogen plasma treatment) on the first source portion and the first drain portion. During the conductivity treatment, the material of the active layer covered by the photoresist-completely-retained region is still semiconductor, and the electrical-conductivity of the first source portion and the first drain portion is increased by the conductivity treatment.

In this step, a NH3 gas plasma treatment is used.

A7, removing the residual photoresist on the base substrate by stripping process.

In an example, the RIE process used in the step A3 and A5 comprises:

using a mixture gas of carbon tetrafluoride (CF₄) and oxygen (O₂) to perform the RIE process; or using oxygen (O₂) to perform the RIE process.

In the TFT array substrate manufacturing by the above method, it should be noted that the active layer, which is covered by the photoresist-completely-retained region, is still semiconductor, and the electrical-conductivity of the first source portion and the first drain portion is improved by the conductivity treatment so as to ensure the normal switching work of the switch TFT.

The manufacturing method provided by the embodiment of the present invention will be described by taking the TFT array substrate illustrated in FIG. 3 as an example.

The manufacturing method of the TFT array substrate according to the embodiment of the present invention comprises the following steps:

1) cleansing a transparent base substrate 1;

2) depositing a metal film with a thickness of 50 nm-400 nm on the base substrate 1 by a sputtering method or evaporation method, and forming a gate pattern 2 and a store capacitance lower electrode 3 pattern by a patterning process;

3) depositing a SiOx film with a thickness of 100 nm-50 nm on the base substrate subjected to above steps by plasma enhanced chemical vapor deposition (PECVD), so as to form a gate insulation layer 4;

4) depositing a IGZO film with a thickness of 10 nm-80 nm on the base substrate subjected to above steps by a sputtering method, and forming an active layer pattern 5′ by a patterning process;

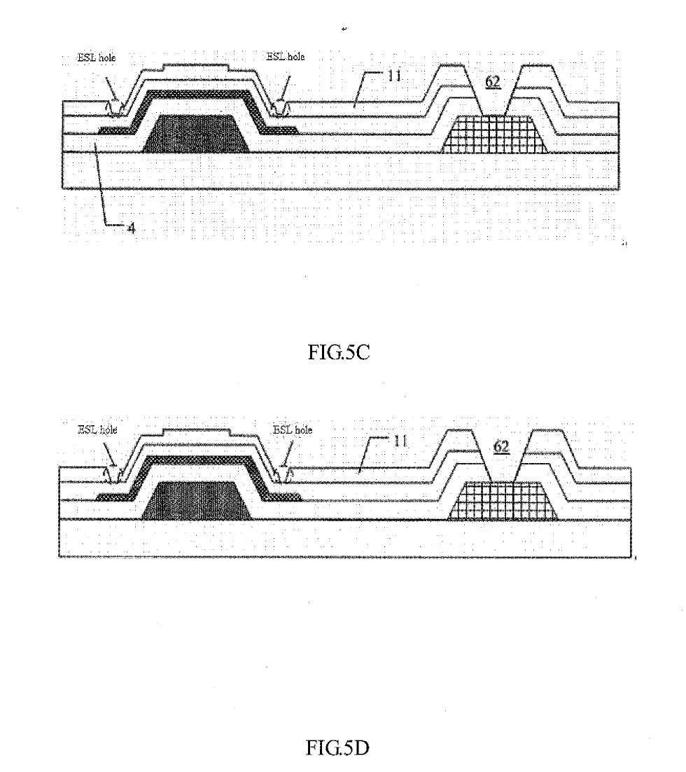

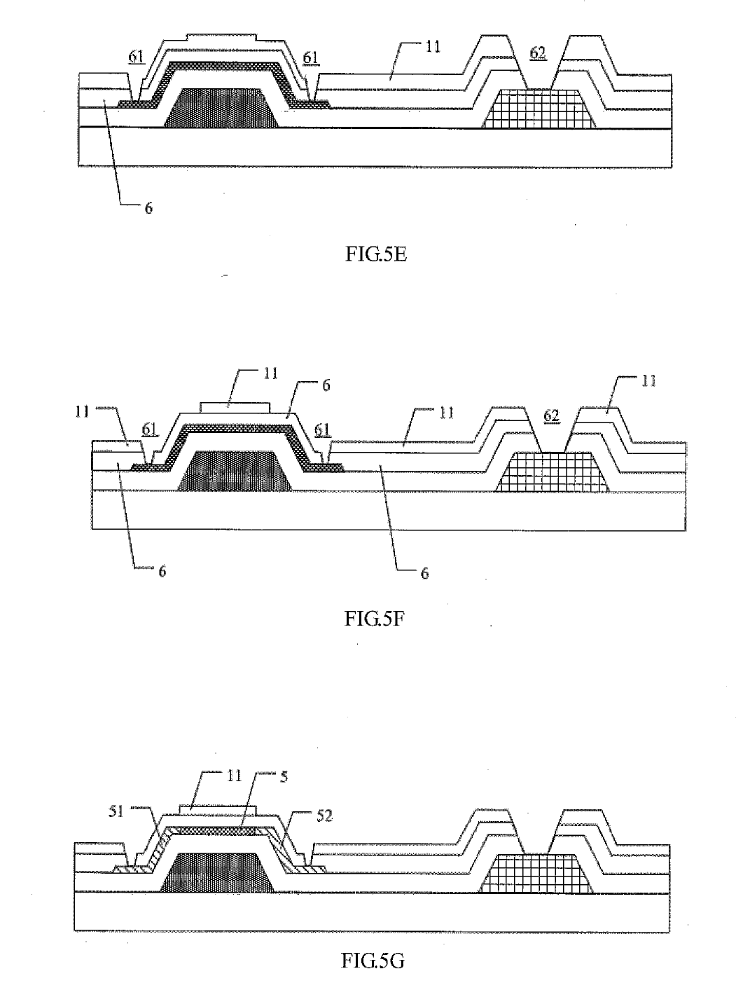

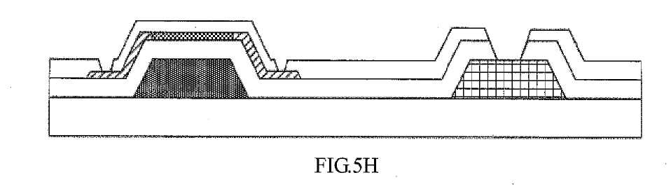

5) forming a SiOx film 6 with a thickness of 40 nm-120 nm on the base substrate subjected to above steps by PECVD or sputtering method; coating a photoresist 11 (PR) on the SiOx film 6, as illustrated in FIG. 5A; exposing and developing the photoresist 11 with a gray tone mask, so as to obtain the structure illustrated in FIG. 5B. It seen from FIG. 5B that the photoresist is divided into five regions after exposing and developing process, wherein the region corresponding to the position of the via hole is the first region, in which the photoresist is completely exposed; the region corresponding to the position of the gate is the second region, in which the photoresist is not exposed; the region corresponding to the position of the ESL hole is the third region, in which the photoresist is partly exposed; the region corresponding to other regions of the first source portion and the first drain portion except the ESL hole is the fourth region, in which the photoresist is partly exposed; the region corresponding to the region other than above regions is the fifth region, in which the photoresist is not exposed. The thickness of the photoresist in the third region is less than the thickness of the photoresist in the fourth region;

Next, a via hole 62 is formed by etching the region corresponding to the via hole (i.e. first region), the obtained structure is illustrated in FIG. 5C; and then, the photoresist in the region of ESL hole 61 and the photoresist remaining in the via hole 62 is removed by RIE process with a mixture gas of CF₄ and O₂, the obtained structure is illustrated in FIG. 5D;

An ESL hole 61 is formed by etching the region corresponding to the ESL hole (i.e. third region), the obtained structure is illustrated in FIG. 5E; then, the photoresist in the other region (i.e. fourth region) of the first source portion and the first drain portion except the region of ESL hole 61 and the photoresist remaining in the ESL hole 61 are removed by RIE process with a mixture gas of CF4 and O2, the obtained structure is illustrated in FIG. 5F; performing hydrogen plasma treatment on the regions at right and left sides of the active layer 5′, thus semiconductor material in the regions at right and left sides of the active layer 5′ is transformed into the conductor so as to form the active layer 5, the first source portion 51 and the first drain portion 52; and the central part of the active layer 5′ (i.e. active layer 5) is still semiconductor because of the protection of the photoresist, as illustrated in FIG. 5G;

Finally, the residual photoresist on the base substrate is removed, the obtained structure is illustrated in FIG. 5H.

6) depositing a metal film with a thickness of 50 nm-400 nm on the base substrate subjected of above process step by a sputtering method, and forming the second source portion pattern of the source and the second drain portion pattern of the drain by a patterning process;

7) depositing a SiOx or SiNx film of 200 nm-400 nm thickness on the base substrate subjected to above process step by PECVD, and forming the passivation layer pattern by a patterning process;

8) depositing an indium-tin oxide (ITO) of 40 nm-150 nm thickness on the base substrate subjected to above process step by sputtering, and forming the store capacitance upper electrode by a patterning process, the obtained structure of the TFT array substrate is illustrated in FIG. 3.

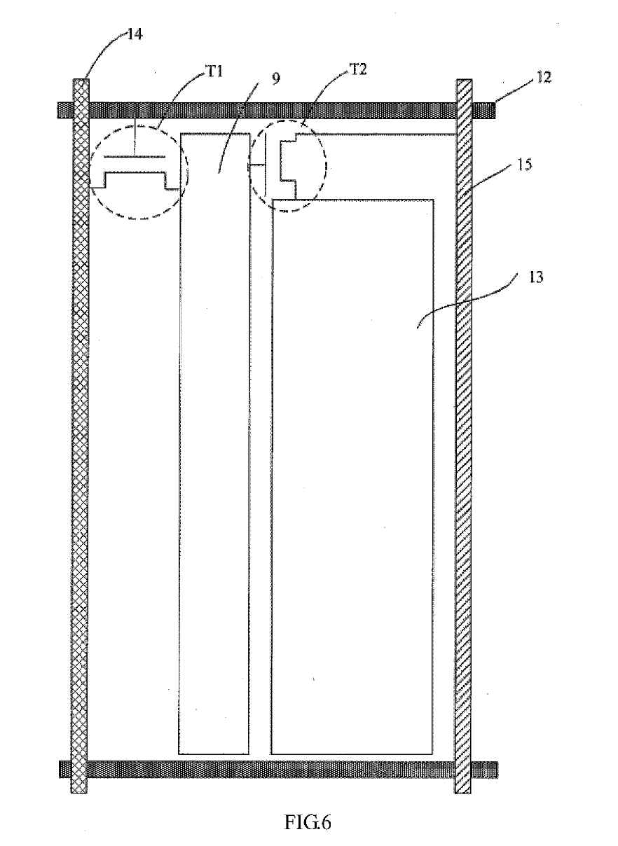

FIG. 6 schematically illustrates a top view of a pixel unit of the AMOLED array substrate formed by the manufacturing method according to the embodiment of the present invention. In FIG. 6, T1 refers to the switch TFT of the pixel unit, T2 refers to the drive TFT of the pixel unit, the gate of T1 is electrically connected to the gate line 12, the second source portion of the source of T1 is electrically connected to the data line 14, the second drain portion of the drain of T1 is connected to the gate of T2 through the store capacitance upper electrode 9, the second source portion of the source of T2 is connected to the VVD line (i.e. power line) 15, and the second drain portion of the drain of T2 is connected to the pixel electrode 13.

It is should be noted that the second source portion of the switch TFT in the pixel unit may be connected to the pixel electrode (as illustrated in FIG. 6), and also may not be connected to the pixel electrode (as illustrated in FIG. 3) in the TFT array substrate according to the embodiment of the present invention

In the embodiment, the source/drain electrode can be formed without an individual patterning process, which shortens the production cycle, reduces production cost and improves production efficiency. The method for manufacturing the array substrate provided by the embodiment of the present invention has the advantages of simple, reliable and easily achieved and has a wide application prospect.

This application claims priority to and the benefit of Chinese Patent Application No. 201310746662.9, filed Dec. 30, 2013, the disclosure of which is incorporated herein by reference in its entirety.

What is described above is related to the illustrative embodiments of the disclosure only and not limitative to the scope of the disclosure; the scopes of the disclosure are defined by the accompanying claims.

1. A thin film transistor (TFT), a source of the TFT comprising a first source portion, a drain of the TFT comprising a first drain portion, wherein the first source portion and the first drain portion are disposed in the same layer as an active layer of the TFT and at two opposite sides of the active layer, and the first source portion and the first drain portion are in direct contact with the active layer respectively.

2. The TFT according to claim 1, wherein the first source portion and the first drain portion are made of a material obtained from subjecting the same material as the active layer to a conductivity treatment.

3. The TFT according to claim 1, wherein the active layer is made of a semiconductor material.

4. The TFT according to claim 1, wherein the TFT further comprises an etch stop layer disposed on the active layer, the first source portion as well as the first drain portion; the source further comprises a second source portion disposed on the etch stop layer; the drain further comprises the second drain portion disposed on the etch stop layer; wherein the second source portion is connected to the first source portion, and the second drain portion is connected to the first drain portion.

5. The TFT according to claim 4, wherein two first via holes penetrating through the etch stop layer and respectively above the first source portion and the first drain portion are disposed in the etch stop layer; the second source portion is connected to the first source portion through one first via hole above the first source portion, and the second drain portion is connected to the first drain portion through the other first via hole above the first drain portion.

6. The TFT according to claim 1, wherein the TFT further comprises a gate disposed above or below the active layer.

7. A TFT array substrate, comprising a plurality of pixel units, wherein each of the pixel units comprises a switch TFT, and the switch TFT is the TFT according to claim 1.

8. The TFT array substrate according to claim 7, wherein the TFT array substrate is an active matrix organic light emitting display (AMOLED) array substrate, each of the pixel units of the TFT array substrate further comprises a drive TFT, and wherein the drive TFT comprises:
a thin film transistor (TFT), wherein a source of the TFT comprises a first source portion, a drain of the TFT comprising a first drain portion, wherein the first source portion and the first drain portion are disposed in the same layer as an active layer of the TFT and at two opposite sides of the active layer, and the first source portion and the first drain portion are in direct contact with the active layer respectively.

9. The TFT array substrate according to claim 8, wherein the AMOLED array substrate further comprises a gate, a gate insulation layer, an etch stop layer and a store capacitance lower electrode, wherein a second via hole penetrating through both the etch stop layer and the gate insulation layer is disposed in the etch stop layer, the store capacitance lower electrode is connected to the gate of the drive TFT through the second via hole, and the store capacitance lower electrode is disposed in the same layer as the gate of the switch TFT.

10. The TFT array substrate according to claim 9, wherein a connection metal layer in the same layer as the second source portion and the second drain portion of the switch TFT is disposed in the second via hole, the gate of the drive TFT is connected to the store capacitance lower electrode through the connection metal layer.

11. The TFT array substrate according to claim 10, wherein the AMOLED array substrate further comprises a pixel electrode, the pixel electrode is connected to the second drain portion of the switch TFT.

12. A display device, comprising the TFT array substrate according to claim 7.

13. A method of manufacturing a TFT array substrate, comprising:
forming a first source portion pattern of a source, a first drain portion pattern of a drain, and an active layer pattern on a base substrate by patterning process, wherein the first source portion and the first drain portion are respectively disposed at two opposite sides of an active layer and in direct contact with the active layer; and
performing a conductivity treatment on the first source portion and the first drain portion.

14. The method according to claim 13, wherein the conductivity treatment comprises hydrogen plasma treatment.

15. The method according to claim 13, wherein the method further comprises the following step before performing a conductivity treatment:
forming an etch stop layer pattern on the base substrate with the active layer formed thereon by patterning process, wherein two first via holes penetrating through the etch stop layer and respectively above the first source portion and the first drain portion are formed in the etch stop layer.

16. The method according to claim 15, further comprising:
forming a second source portion pattern of the source and a second drain portion pattern of the drain on the base substrate with the etch stop layer formed thereon by patterning process; the second source portion is connected to the first source portion through one first via hole above the first source portion, and the second drain portion is connected to the first drain portion through the other first via hole above the first drain portion.

17. The method according to claim 16, further comprising:
forming a gate and a passivation layer on the base substrate with the second source portion and the second drain portion formed thereon by patterning process.

18. The method according to claim 13, wherein before the step of forming the first source portion pattern of the source, the first drain portion pattern of the drain and the active layer pattern, the method further comprises:
forming a gate pattern and a gate insulation layer on the base substrate by patterning process.

19. The method according to claim 18, wherein the TFT array substrate is an active matrix organic light emitting display (AMOLED) array substrate, the method further comprises the following step while simultaneously forming the gate pattern on the base substrate:
forming a store capacitance lower electrode pattern in the same layer as the gate.

20. The method according to claim 19, wherein the step of forming the etch stop layer pattern on the base substrate with the active layer formed thereon by patterning process further comprises:
forming a second via hole which penetrates through both the etch stop layer and the gate insulation layer in the etch stop layer; wherein the store capacitance lower electrode is connected to the gate of the drive TFT by the second via hole.
